(19) United States
(12) Patent Application Publication
(10) Pub. No.: US 2005/0011770 A1
(43) Pub. Date: Jan. 20, 2005

(54) Reduction method of atmospheric carbon dioxide, recovery and removal method of carbonate contained in seawater, and disposal method of the recovered carbonate

(76) Inventors: Tatenuma Katsuyoshi, Ibaraki-ken (JP); Yoshida Kosuke, Ibaraki-ken (JP); Arai Osamu, Ibaraki-ken (JP); Suzuki Jun, Ibaraki-ken (JP); Kurosawa Kiyoko, Ibaraki-ken (JP)

Correspondence Address: FLYNN THIEL BOUTELL & TANIS, P.C., 2026 RAMBLING ROAD, KALAMAZOO, MI, 49008-1699, US

(21) Appl. No.: 10/623,368

(22) Filed: Jul. 18, 2003

(51) Int. Cl. B01J 2/00; C30B 7/12

(52) U.S. Cl. 205/742; 205/687

(57) ABSTRACT

The invention relates to a global reduction method of the concentration of atmospheric carbon dioxide, which is one of the green house gas and the most causative substance to the earth warming, by direct electrolysis treatment of the surface ocean water.

### BACKGROUND OF THE INVENTION

1. Field of the Invention

The invention relates to a global reduction method for the concentration of atmospheric carbon dioxide (CO₂) which is one of the green house gas and the most causative substance to the earth warming.

2. Description of Prior Art

The technologies conventionally developed for a sectional reduction method for the concentration of atmospheric CO₂ emitted from thermal power plants or cement producing plants are chemical absorption method of CO₂ by organic amine compounds, isolation or dissolution method of the recovered CO₂ to ocean, chemical conversion method of CO₂ to methane as the resource material, and other many technologies have been researched and developed. Furthermore, as a global reduction method for the concentration of atmospheric CO₂ emitted and accumulated in the atmosphere, natural immobilization method such as afforestation, algal growth, fertilizer application to the ocean, and coral reef growth have been studied and attempted. However, these method mentioned above individually have problems in cost, energy, environment, and efficiency, and a decisive global solution method has not been developed yet.

### SUMMARY OF THE INVENTION

In comparison with the technologies conventionally developed for a sectional and global reduction method for the concentration of CO₂, the invention gives a fundamental and a decisive solution for the problems of global warming by globally reducing CO₂ which has been accumulated in the atmosphere utilizing ocean.

The invention is a practical and global reduction method for the concentration of atmospheric CO₂, and is characterized by; a possibility of a reduction capability of emitted and emitting CO₂, a controllable method for the reduction amount of CO₂, a stable isolation method of the atmospheric CO₂ from the biosphere, a method without generating the secondary waste or CO₂ emission through the treatment, a low cost and energy-saving method, a method without chemical or biological additives to the ocean, and a method without disturbing the earth's ecosystems. According to the invention, it is possible to solve the social and economical problems led by the earth warming problems, and it is not necessary to restrain the economical growth.

The invention relates to a practical reduction method for the concentration of the global atmospheric CO₂. According to the invention, the method does not restrain the economical growth, and it is possible to reduce not only the concentration of CO₂ accumulated in the atmosphere from the past but also the CO₂ continuously emitted to the atmosphere from now on. Furthermore, it is expected that the excess amount of CO₂ accumulated in the atmosphere will be stably isolated from the biosphere with moderate control to maintain the proper environment.

The invention is a global reduction method for the concentration of atmospheric CO₂ that by utilizing the chemical equilibrium occurred at the contacting interface between the atmosphere and the superficial ocean water, the atmospheric CO₂ is absorbed and reduced into the superficial ocean water of which carbonate concentration is reduced by a removal treatment of carbonate such as bicarbonate and carbonate ions contained in the surface ocean water.

As a removal method of the carbonate from the surface ocean water absorbing the CO₂, calcium, magnesium, and carbonate, which are coexisting in the ocean water, are chemically combined to form an insoluble carbonate salt without adding any additives to the ocean water.

Moreover, as a recovery method of the carbonate dissolved in the ocean water, carbonate is separated as a form of insoluble carbonate precipitates, and the carbonate precipitate is settled down to the ocean bottom and deposited.

The process according to the invention is that the decarbonated surface ocean water which carbonate is removed absorbs the atmospheric CO₂ by the chemical equilibrium occurred at the contacting interface between the atmosphere and the superficial ocean water, calcium, magnesium, and carbonate, which are coexisting in the ocean water, are chemically combined and recovered as a form of insoluble carbonate precipitate, and the insoluble carbonate precipitates are settled down to the ocean bottom as a solid form and deposited.

In the process mentioned above according to the invention, direct electrolysis treatment is carried out to the superficial ocean water in order to form the insoluble carbonate precipitate without any additives to the ocean water.

By the electrolysis treatment used in the process according to the invention aiming at the global reduction for the concentration of the atmospheric CO₂, the concentration of hydrogen ion in the ocean water treated by the electrolysis is lower than that of the ocean water untreated by electrolysis, and the absorption capability of the atmospheric CO₂ to the superficial ocean water is therefore increased. In the process of the electrolysis treatment to the ocean water, hydrogen gas simultaneously generated during the electrolysis treatment is recovered and recycled as a hydrogen resource.

By the global reduction method of the concentration of atmospheric CO₂ according to the invention, there will be better social and economical effects compared to the conventionally developed sectional reduction method. According to the invention, it is not necessary to restrain the CO₂ emission led by the economical growth in the developing country. In the meantime, in order to progress with the treatment for removing carbonate from the seawater, it is necessary to build an international consensus.

### BRIEF DESCRIPTION OF THE DRAWINGS

FIG. 1 is an image shows the basic principle of the global reduction method of the atmospheric CO₂ by the electrolysis treatment of the superficial ocean water.

FIG. 2 is an image shows a principle of the electrolysis treatment of ocean water by the flow type electrolysis cell.

FIG. 3 is an image shows a process of decarbonation of ocean water by the decarbonation system.

### DETAILED DESCRIPTION OF PREFERRED EMBODIMENT

Hereinafter, preferred embodiments of the invention will be concretely described with referent to the drawings and the chemical equations.

As a global reduction method of the concentration of the atmospheric CO₂ according to the invention, average concentration of 2.0˜2.2 mmol/kg carbonate contained in the superficial ocean water as forms of carbonate and bicarbonate ions is allowed to react with calcium (Ca: 10 mmol/kg in ocean water) and magnesium (Mg: 53 mmol/kg in ocean water), and insoluble Ca—Mg carbonate is formed. And the carbonate in the superficial ocean water is removed as a insoluble carbonate precipitate. The superficial ocean water decarbonated absorbs the atmospheric CO₂ by the chemical equilibrium occurred at the contacting interface between the atmosphere and the surface of ocean, and the concentration of atmospheric CO₂ is then reduced.

Salts dissolved in the ocean water are mostly existing as the forms of ions and ionic pairs, and the ocean water is therefore the electrolyte solution with high electrical conductivity. By utilizing this characteristics of the ocean water mentioned above, electrolysis is directly carried out to the ocean water and the form of the carbonate contained in the ocean water is changed to the insoluble carbonate. The electrolysis reaction proceeded by the direct electrolysis of the ocean water utilizing a flow type electrolysis cell with two electrodes (anode and cathode) and a porous membrane between them, at the cathode, reaction (2) is proceeded by OH produced by the water decomposition reaction (1), and the carbonate dissolved in the ocean water is then precipitated as a form of insoluble calcium carbonate (CaCO₃). The actual precipitate is a form of basic carbonate salt [CaCO₃·Mg(OH)₂] in addition. On the other hand, at the cathode, reaction (3) is mainly proceeded rather than the water decomposition reaction, and moreover the hydrolysis reaction (4) is proceeded. Reaction (5) is a total electrolysis reaction of the ocean water, and according to the invention, it is identify by the reaction (5) and the experimental results that there is no carbon dioxide gas emission through the electrolysis treatment of the ocean water. The mixture of the ocean water treated at the anode and cathode is alkalinized, and the adsorption capability of the atmospheric CO₂ is increased in comparison with untreated ocean water.
2H₂O+2e⁻àH₂+2OH⁻ (1)
Ca²⁺+Mg²⁺+HCO₃⁻+OH⁻àCa (Mg) CO₃<precipitate>+H₂O (2)
2Cl⁻àCl₂+2e⁻ (3)
Cl₂+H₂Oà2H⁺+ClO⁻+Cl⁻ (4)
2H₂O+2Cl⁻+(2Na⁺+4Cl⁻)+Ca²⁺+xMg²⁺+2HCO₃⁻à2H₂+CaCO₃·xMg(OH)₂<precipitate>+CO₃²⁻+2HClO(+2NaCl) (5)

In the meantime, it is not expected to use the coral reef as a CO₂ absorbent because the same molar amount of CaCO₃ and CO₂ is generated by the carbonate fixation reaction of the coral reef as shown in the equation (6). On the other hand, according to the invention indicated by the reaction (5), there is no CO₂ emission by the electrolysis reaction of the ocean water, and therefore, the electrolysis reaction of the ocean water according to the invention is different from the carbonate fixation reaction of the coral reef.
Ca²⁺+2HCO₃⁻àCaCO₃<precipitate>+CO₂<emission>+H₂O (6)

The solid basic carbonate generated by the electrolysis treatment of the ocean water is gathered by the oceanic current inside of the flow type electrolysis cell, and it is then settled down to the ocean bottom by its own weight as a solid form. As a result, the concentration of the carbonate ion in the superficial ocean water is decreased, and the transfer speed of the carbonate component from the surface layer of the ocean to the deeper layer is possibly increased. In addition that the transfer speed of the carbonate component from the superficial layer of the ocean to the deeper layer is a rate limiting factor causing slow absorption speed of the atmospheric CO₂ to the surface ocean water.

By the process mentioned above, the carbonate component dissolved in the superficial ocean water is settled down to the ocean bottom as the insoluble carbonate compound by its own weight and deposited. As a result of that the atmospheric CO₂ is absorbed by the decarbonated ocean water produced by the electrolysis, the reduction of excess amount of accumulated atmospheric CO₂ as a main greenhouse effect gas causing the earth warming is promoted. A principle of the invention is shown in FIG. 1.

The reduction method of the excess amount of atmospheric CO₂ according to the invention is a technology that, it is not necessary to add any chemical or biological additives to the ocean, it is possible to control the reduction amount of the atmospheric CO₂ artificially, and it is an environmentally thoughtful method because slight decrease in the concentration of hydrogen ion is an only effect by the electrolysis treatment of the ocean water. In comparison with the conventionally developed method which requires the process of CO₂ recovery from the thermal power plants or the cement producing plants and treatment of the recovered CO₂ to the gaseous substance or dry-ice for its disposal, the reduction method of the atmospheric CO₂ according to the invention has many advantages that the large amount of energy is not necessary for the process of CO₂ recovery and disposal, and furthermore, there is no acidification problem of the ocean water led by direct disposal of the recovered CO₂. In the case utilizing the clean electric energy such as solar power, wind power, H₃—O₂ fuel cell power or ocean thermal energy conversion for the reduction of the atmospheric CO₂ according to the invention, the ratio of the CO₂ emission amount from the reduction treatment of atmospheric CO₂ and removable amount of atmospheric CO₂ by the treatment is 1/10-1/20.

To complete the above description, five implementation examples of the process according to the invention are given bellow.

### EXAMPLE 1

Electrolysis treatment of the ocean water was carried out using a flow type electrolysis cell consisted of two cylindrical titanium mesh with different bore diameters coated with platinum as electrodes placed in a cylindrical electrolysis cell (internal diameter: 96 mm, length 500 mm) while keeping 20 mm between on e electrode and another, and a cylindrical porous membrane (polypropylene, pore size: 50-300 m) with the external diameter of 70 mm and the internal diameter of 55 mm place between two cylindrical electrodes. Constant flow rate of 1-4 L/min. of ocean water was allowed to flow through the electrolysis cell, and direct current voltage was impressed between two cylindrical electrodes.

As a result of the experimental electrolysis treatment, it was clarified that the carbonate contained in the ocean water is removed as a form of insoluble carbonate precipitate, and the effectiveness of the invention was confirmed. Precipitation of a fine and white material was begun at the electrolysis current density of approximately 6˜8 mA/cm², and the precipitation was then activated at the electrolysis current density of approximately 20˜30 mA/cm². The precipitate produced by the electrolysis was basic carbonate containing CaCO₃ and Mg(OH)₂. In addition to the electrolysis conditions, it was possible to control the decarbonation yield in the range of approximately 20% to 70% by controlling the electrolysis current density. By the experimental results mentioned above, the formation reaction of the insoluble carbonate precipitate is proceeded with the constituents of the ocean water without any additives, and the effectiveness of the decarbonation treatment of the ocean water was confirmed. The solid carbonate is low in the solubility to the ocean water, and therefore the solid carbonate can be deposited to the ocean bottom. It is expected that the solid carbonate deposited on the ocean bottom can be mineralized for extended period of time. According to the invention, in comparison with the conventionally developed methods such as direct injection disposal of CO₂ gas or the dry-ice, there is no CO₂ remission from the process.

### EXAMPLE 2

Recovery of hydrogen gas generated at cathode during the electrolysis treatment of the ocean water according to the invention was carried out by the same experimental condition as Example 1. As a result of the experiment, it was confirmed that the fine bubble produced at the cathode during the electrolysis treatment was hydrogen gas and the generation rate of the hydrogen gas was in proportion to the coulomb amount of the electrolysis treatment. A relation between energy consumption to be used for the electrolysis treatment and hydrogen gas generation was obtained as 2-4 mol/kWh. In addition to the hydrogen gas generated at the cathode, the hydrogen gas can be easily recovered since the permeability of the hydrogen gas to the gas separation film is high. Furthermore, The purity of the recovered hydrogen gas was higher than 95%, and the gas can be used as a resource gas for the O₂—H₂ fuel cell.

### EXAMPLE 3

Compositions and forms of the insoluble carbonate generated by the electrolysis treatment of the ocean water according to the invention are dependent on the conditions of electrolysis treatment; the carbonate (low basic carbonate) with low basicity and high calcium carbonate contents is generated under the electrolysis treatment with low current density, and carbonate (high basic carbonate) with high basicity and low calcium carbonate contents is generated under the electrolysis treatment with high current density. Property of the carbonate is dependent on its shape and particle size, and the sedimentation speed of the produced carbonate in the ocean water with the ambient pressure is approximately 1-10 m/h which is much faster than the transfer speed of the components from surface ocean water to the deeper layer (approximately 1 cm/y). Furthermore, as a result of the pressurization treatment of the produced carbonate with the highly pressurized ocean water of 300-500 kg/cm², CaCO₃ content in the carbonate and specific gravity is relatively increased by the eluviation of Mg(OH)₂ contained in the carbonate. As a result, the transfer speed of the carbonate is increased, and the mineralization of the carbonate can be proceeded.

### EXAMPLE 4

The decarbonated ocean water containing ClO⁻ of 20-30 ppm produced by the anode electrolysis as mentioned in the equation (3) and (4) cannot be released from the electrolysis cell to the ocean since ClO⁻ is hazardous to the marine organizations. As for the removal treatment of ClO⁻, ClO⁻ can be completely decomposed by contacting with the activated carbon, and generation of carbon monoxide and CO₂ is not occurred by the decomposition treatment. By the decomposition treatment of ClO⁻ contained in the decarbonated ocean water, the decarbonated ocean water is further alkalined because of the consumption of hydrogen ion led by the decomposition reaction of ClO⁻ as shown in the equation (7).
ClO−+2H⁺−2e⁻à (treatment by activated carbon) à Cl⁻+H2O (7)

### EXAMPLE 5

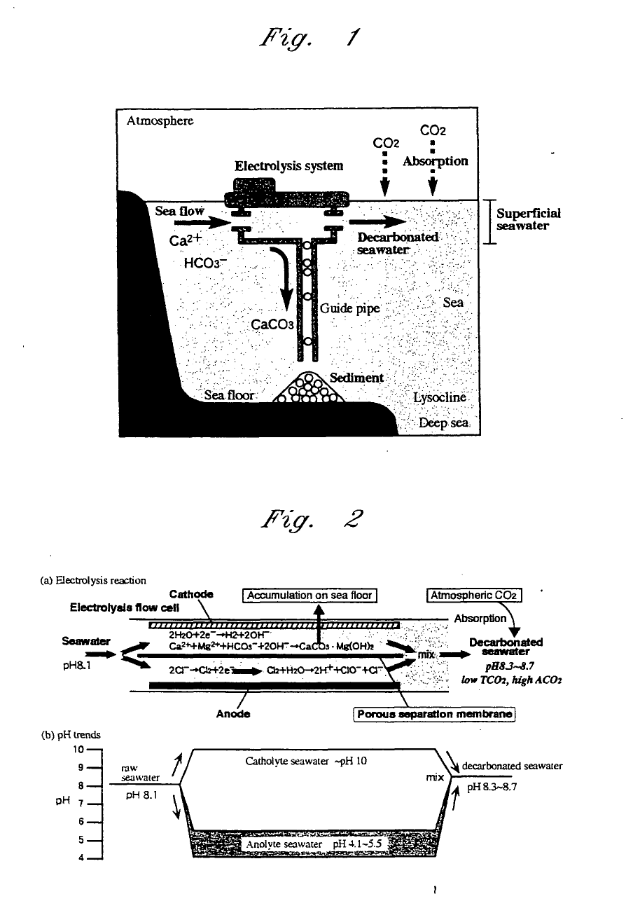

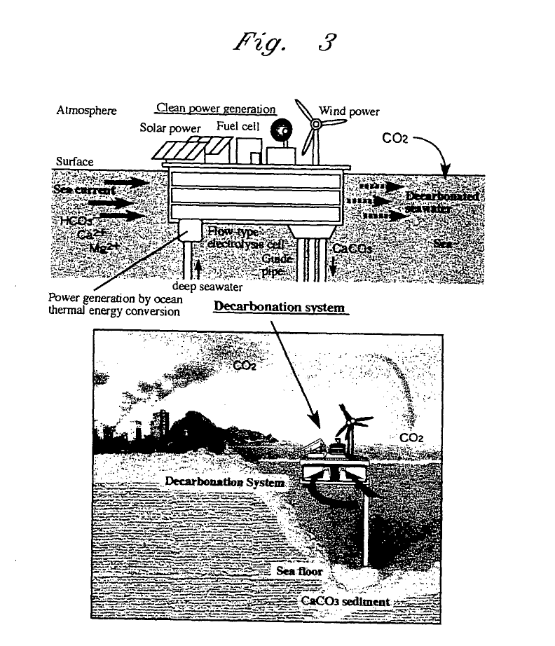

In order to realize the invention, it is necessary to create the concrete measure for the separation recovery of carbonate in the ocean water as a form of insoluble carbonate and disposal of the recovered solid carbonate to the ocean bottom. As the concrete measure, a flow type electrolysis cell shown in FIG. 2 is set on the surface of the ocean where the ocean current is continuously flowing, and electrolysis treatment is carried out to the ocean water in the cell by utilizing the natural oceanic flow. Insoluble carbonate is then produced by the electrolysis treatment in the electrolysis cell. The flow type electrolysis cell is needed to be design to perform a process for the disposal of the insoluble carbonate produced as follows; the insoluble carbonate produced by the electrolysis treatment is gathered in the electrolysis cell by utilizing the oceanic flow and is led into a guide pipe for disposal onto a sea floor. For example, the system is placed on the surface of seas close to Japan where the Kuroshio Current with average flow late of 1 m/s is flowing, in order to remove carbonate of 1 GtonC/y (GtonC: 10⁹ ton as carbon, The amount of 1 GtonC/y is equivalent to ⅙ of the whole CO₂ emission by combustion of fossil fuel, and to ⅓ for preventing the accumulation in the atmosphere) from seawater, the effective area of the current intake dimension of the system with 25-50% removal efficiency is necessitated to be 2.28-4.56×10⁶ m². Due to the fact that 100 m depth of ocean layer is the place where the chemical equilibrium occurs between the atmosphere and surface ocean water, the depth of the system is 100 m then the width will be 22,800-45,600 m. The decarbonation system is shown in FIG. 3

The system mentioned above is mainly composed of the electrolysis cell and the power generator for the electrolysis treatment, and it is preferable to utilize the clean energy such as solar power, wind power, H₂—O₂ fuel cell power (it is possible to use the hydrogen gas generated by the electrolysis treatment of the ocean water as resource gas) or ocean thermal energy conversion. As to the energy requirement for the electrolysis treatment of the ocean water, approximately 1.4×10⁹ kW (assuming decarbonation efficiency of 25-50%) is required to treat 1 GtonC/y of carbonate. On the assumption that the world total CO₂ amount to be reduced in one year to solve the global warming is 3 GtonC/y, it is necessary to built 3 systems with the same decarbonation efficiency as above. The system is required to have strong structure because the system is exposed to the strong ocean flow, wind and waves for a long period of time.

1. A global reduction method of the atmospheric carbon dioxide comprising a process of; the decarbonated surface ocean water, of which the concentration of carbonate is reduced by removing carbonate ions such as bicarbonate ion and carbonate ion, absorbs the atmospheric carbon dioxide by chemical equilibrium occurred at the contacting interface between atmosphere and superficial ocean water.

2. A recovery and reduction method of carbonate from surface ocean water by reacting the coexisting substances, calcium, magnesium, and carbonate, without any additives to the ocean.

3. A recovery method of carbonate dissolved in the ocean water comprising the steps of; separation of the carbonate from ocean water as the insoluble carbonate precipitates, and sedimentation disposal of the insoluble carbonate precipitates to ocean bottom.

4. A process comprising the steps of; absorption of atmospheric carbon dioxide to the decarbonated surface ocean water by the chemical equilibrium occurred at the contacting interface between atmosphere and surface ocean water, recovery and reduction of carbonate from superficial ocean water by reacting the coexisting substances, calcium, magnesium, and carbonate to form the insoluble carbonate precipitates, and sedimentation disposal of the insoluble carbonate precipitates to ocean bottom.

5. A process according to claim 1, the reduction method of the concentration of carbonate contained in the superficial ocean water is carried out by the direct electrolysis treatment of ocean water without any additives.

6. A process according to claim 5 comprising the steps of, increase of carbon dioxide absorption capacity of the ocean water treated by the direct electrolysis led by decrease of the concentration of hydrogen ion in the treated ocean water.

7. A process according to claim 5, recovery and recycling of hydrogen gas generated simultaneously by the electrolysis treatment of ocean water.
